(19) United States
(12) Patent Application Publication
(10) Pub. No.: US 2010/0037824 A1
(43) Pub. Date: Feb. 18, 2010

(54) Plasma Reactor Having Injector

(75) Inventor: Sang In LEE, Sunnyvale, CA (US)

Correspondence Address: FENWICK & WEST LLP, SILICON VALLEY CENTER, 801 CALIFORNIA STREET, MOUNTAIN VIEW, CA, 94041, US

(73) Assignee: Synos Technology, Inc., Sunnyvale, CA (US)

(21) Appl. No.: 12/539,142

(22) Filed: Aug. 11, 2009

Related U.S. Application Data
(60) Provisional application No. 61/088,670, filed on Aug. 13, 2008.

(51) Int. Cl. C23C 16/06

(52) U.S. Cl. 118/723 R

(57) ABSTRACT

A plasma reactor includes a plasma generator configured to spray plasma, and an injector located adjacent to the plasma generator and configured to inject a precursor to the plasma sprayed from the plasma injector. The injector includes a platform having an opening, at least one injection hole formed in the platform to inject the precursor to the opening, and a channel formed in the platform to connect with the at least one injection hole to carry the precursor. The plasma reactor may allow supply of the plasma together with the precursor. In case corona plasma is used where a vacuum state is not needed, a wider process window may be ensured.

### CROSS-REFERENCE To RELATED APPLICATION

This application claims priority under 35 U.S.C. §119(e) to co-pending U.S. Provisional Patent Application No. 61/088,670 entitled “New Arc Plasma Source with Pre-Cursor Injector,” filed on Aug. 13, 2008, which is incorporated by reference herein in its entirety.

### BACKGROUND

1. Field of Art

This invention relates to a plasma reactor having an injector for fabricating a film on a semiconductor.

2. Description of Related Art

Plasma is often employed in semiconductor fabrication processes for forming a film on a substrate by atomic layer deposition (ALD) or chemical vapor deposition (CVD). Various kinds of plasma reactors may be used for spraying plasma to the substrate. A parallel plate plasma reactor is one example of such plasma reactors. The parallel plate plasma reactor applies the plasma to a substrate by positioning the substrate between parallel electrodes located in a chamber and then applying power between the electrodes to generate plasma.

Another example of the plasma reactors is an inductively coupled plasma (ICP) type reactor. In an ICP type reactor, a coil is wound around a dielectric reactor made of quartz or the like. Electric current is applied to the coil and varied to generate an induced magnetic field in the coil. The ICP reactor generates plasma by using a secondary induced current that is generated in the reactor as a result of the generated induced magnetic field.

### SUMMARY

Embodiments relate to a plasma reactor configured to generate and spray plasma (for example, corona plasma) onto a substrate together with a material such as a precursor. An injector is provided to provide the precursor material. The plasma reactor may include a plasma generator configured to generate the plasma. The injector is located adjacent to the plasma generator and configured to inject a precursor to the plasma generated by the plasma generator.

In one embodiment, the injector includes a platform. An opening, at least one injection hole and a channel is formed on the platform. The at least one injection hole is formed in the platform to inject the precursor into the opening. The channel is formed in the platform and connected with the at least one injection hole to convey the precursor.

In one embodiment, the plasma generator includes a chamber, first and second electrodes, and a power source. The chamber receives a reaction gas that is injected via an injection port. The first and second electrodes face each other and form an electric field in the reaction gas in the chamber as voltage is applied across the electrodes. The power source applies voltage across the first electrode and the second electrode.

In one embodiment, the plasma reactor forms a deposition film on a substrate or doping or plasma-treating materials on the substrate by supplying plasma together with a precursor. When corona plasma is used as plasma, a vacuum state may not be required, which increases the process window associated with plasma treatment.

### BRIEF DESCRIPTION OF THE DRAWINGS

FIGS. 1a to 1c are sectional views illustrating plasma reactors according to embodiments.

FIGS. 2a and 2b are schematic perspective views illustrating injectors of the plasma reactors in FIGS. 1a to 1c, according to embodiments.

FIGS. 3a and 3b are sectional views illustrating plasma reactors, according to other embodiments.

FIGS. 4a and 4b are schematic perspective views illustrating injectors of the plasma reactors of the plasma reactors in FIGS. 3a and 3b, according to embodiments.

### DETAILED DESCRIPTION

Embodiments are described herein with reference to the accompanying drawings. This disclosure may, however, be embodied in many different forms and should not be construed as limited to the embodiments set forth therein. Rather, these embodiments are provided so that this disclosure will be thorough and complete, and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements. The shape, size and regions, and the like, of the drawing may be exaggerated for clarity.

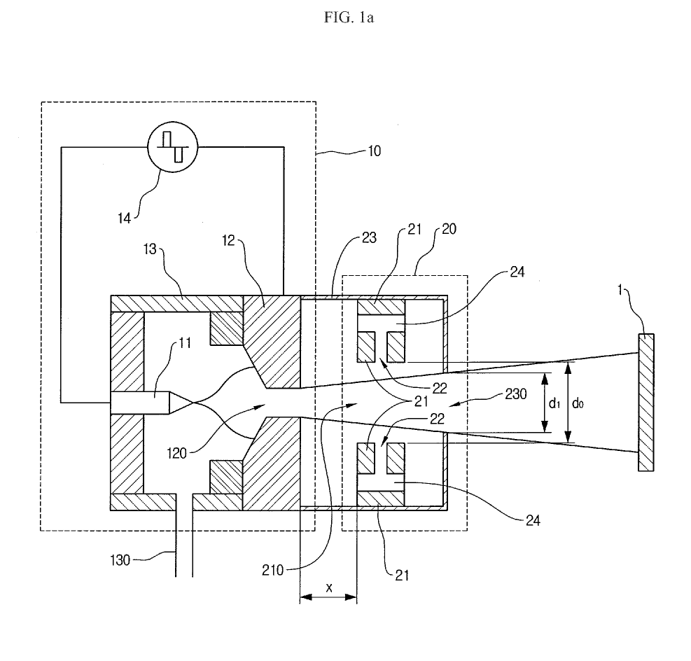

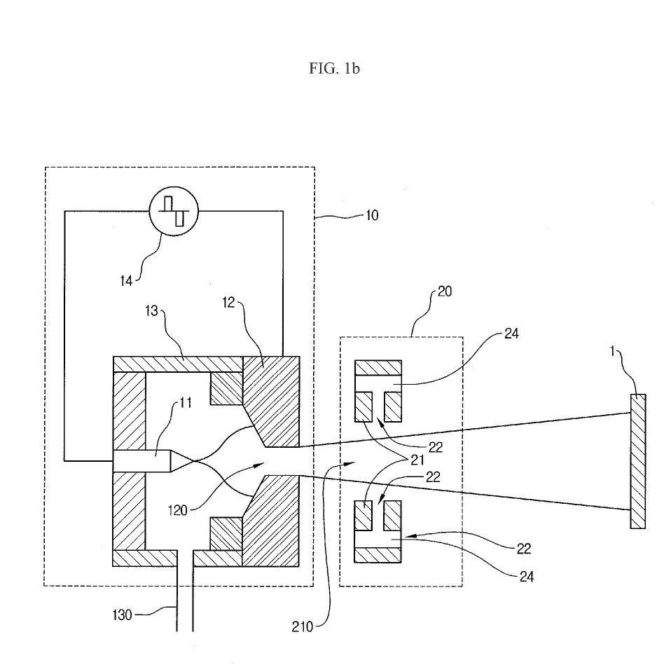

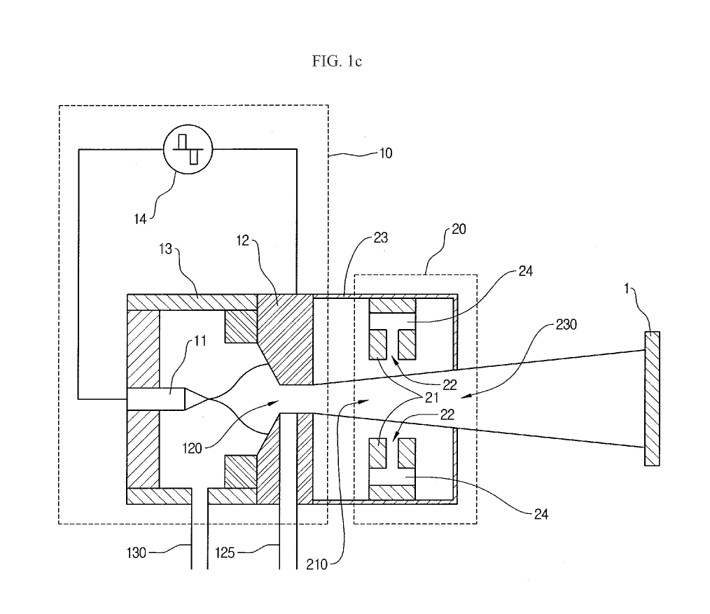

FIG. 1a is a schematic sectional view illustrating a plasma reactor, according to one embodiment. The plasma reactor may include, among others, a plasma generator 10 and an injector 20. The plasma generator 10 and the injector 20 may be located adjacent to each other, and plasma generated from the plasma generator 10 may be ejected onto a substrate 1 together with a material (for example, a precursor) injected from the injector 20.

The plasma generator 10 may include, among others, a chamber 13, a first electrode 11, a second electrode 12 and a signal generator 14. The first electrode 11 and the second electrode 12 may face each other to form plasma in the chamber 13. The chamber 13 may include, among others, an injection port 130. Reaction gas for generating plasma may be injected into the chamber 13 through the injection port 130. The first electrode 11 may be a cylindrical electrode having a sharp tip (for example, a conical shape), and the second electrode 12 may be a flat plate electrode. The second electrode 12 may have an opening 120 through which plasma is discharged. An end portion of the first electrode 11 may be aligned with the opening 120of the second electrode 12.

The signal generator 14 may be a power supply that provides a pulse or square wave pattern voltage signal across the first electrode 11 and the second electrode 12. When the voltage signal is applied between the first electrode 11 and the second electrode 12, an electric field may be formed in the reaction gas present in the chamber 13. The electric field generates corona plasma between the first electrode 11 and the second electrode 12. The generated corona plasma may then be sprayed through the opening 120 of the second electrode 12.

In the embodiment of FIG. 1a, the plasma generator 10 is configured to generate corona plasma. The corona plasma, however, is merely an example. Other kinds of plasma generators may also be used in other embodiments.

The injector 20 may be located adjacent to the plasma generator 10. The injector 20 may be configured to inject materials such as a precursor. The precursor is defined herein as a material that may be used for forming a deposition layer on the substrate 1 or doping a material on the substrate 1 using plasma. The precursors used in the plasma reactor according to the embodiments are described below in detail.

The distance x between the injector 20 and the plasma generator 10 may be set differently depending on the structure of the plasma reactor. That is, the injector 20 may be a variable injector. For example, if a precursor having a relatively high melting point, relatively low vapor pressure and low reactivity is used, the distance x may be relatively small. In this case, the diffusion rate of the precursor to the substrate 1 is decreased. In contrast, if a precursor having a relatively low melting point, relatively high vapor pressure and high reactivity is used, the distance x may be set relatively large. In this case, the diffusion rate of the precursor to the substrate 1 is increased.

The injector 20 may include, among others, a platform 21. The platform 21 may include at least one injection hole 22, and a channel 24. The platform 21 may have an opening 210 with a diameter d0, and the opening 210 may be aligned with the opening 120 of the second electrode 12 through which the plasma is sprayed from the plasma generator 10. The diameter d0 of the opening 210 may be set depending on the size of a region to which the plasma and the precursor are sprayed.

The injection hole 22 injects a precursor to the opening 210. The injection hole 22 may be connected to the channel 24 in the platform 21. The injector 20 may include, among others, an injection port (not shown) for injecting the precursor to the channel 24. The precursor is provided from an external source, carried through the channel 24 to the opening 210, and injected through the injection hole 22.

In one embodiment, the injector 20 may include, among others, a chamber 23 coupled to the plasma generator 10. In this case, the platform 21 may be located in the chamber 23. In case a vacuum condition is required for plasma generation, the platform 21 may be located in the chamber 23 that can be maintained in a vacuum state. The chamber 23 may have a discharge hole 230 for injecting the plasma and the precursor. The discharge hole 230 may be aligned with the opening 210 of the platform 21. The diameter d1 of the discharge hole 230 may be set depending on the size of the region onto which the plasma and the precursor are to be injected.

Corona plasma may be generated even in a non-vacuous state. Hence, in other embodiments, the platform 21 may be located in an open space as illustrated in FIG. 1b, without using the chamber. Since the vacuum state is not required when using corona plasma, a wider process window may be allowed.

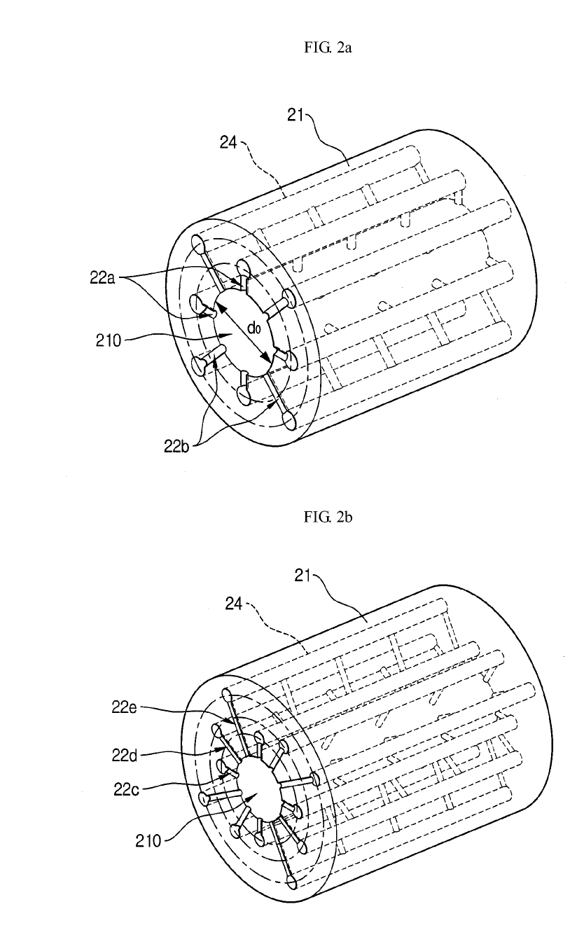

FIG. 2a is a schematic perspective view illustrating an injector included in the plasma reactor, according to one embodiment. The injector 20 as illustrate in FIGS. 1a to 1c may correspond to a partial vertical-sectional view of the injector as illustrated in FIG. 2a. Referring to FIG. 2a, the injector may include, among others, a platform 21, at least one injection hole 22a, 22b, and a channel 24. The platform 21 may be cylindrical and have an opening 210. The opening 210 may extend along the longitudinal direction of the platform 21. The cross-section of the opening 210 perpendicular to the longitudinal direction may be circular and have a diameter of d0. In other words, the platform 21 may be cylindrical with hollow center and have a cylindrical opening 210.

The opening 210 may have eight injection holes 22a, 22b extending in the radial direction of the platform 21. In other words, in one radial cross-section of the platform 21, eight injection holes 22a, 22b may be arranged on the periphery of the opening 210. Each of the eight injection holes 22a, 22b may be separated by a constant circumferential interval.

In one embodiment, the eight injection holes 22a, 22b are repeatedly formed at regular intervals in the longitudinal direction of the platform 21. Among the injection holes 22a, 22b, the holes located at the same position on the periphery may be connected with each other by means of the channel 24 extending in the longitudinal direction of the platform 21. As shown in FIG. 2, for example, if eight injection holes 22a, 22b are formed in one section of the platform 21, a total of eight channels 24 are formed in the platform 21.

The eight injection holes 22a, 22b may be classified into first injection holes 22a and second injection holes 22b depending on the distance from the center of the platform 21 to the corresponding channel 24. In other words, four first injection holes 22a may be located on a first periphery at the section of the platform 21, and four second injection holes 22b may be located on a second periphery at the section of the platform 21.

In one embodiment, different kinds of precursors are injected through the first injection holes 22a and the second injection holes 22b. For example, in case a plasma reactor is used for atomic layer deposition (ALD), it is possible to inject a source precursor through the first injection holes 22a and also inject a reaction precursor through the second injection holes 22b.

FIG. 2b is a schematic perspective view showing an injector included in the plasma reactor, according to one embodiment. The injector as shown in FIG. 2b is similar to the injector of FIG. 2a, and thus, the injector of FIG. 2b is described below primarily with reference to features different from the injector of FIG. 2a.

Referring to FIG. 2b, twelve injection holes 12c, 12d, 12e are formed in total in one cross-section of the platform 21. The twelve injection holes 12c, 12d, 12e are classified into third injection holes 22c, fourth injection holes 22d and fifth injection holes 22e depending on the distance from the center of the platform 21 to the corresponding channel 24. In one embodiment, different kinds of precursors are injected through the third injection holes 22c, the fourth injection holes 22d and the fifth injection holes 22e, respectively.

The shape and number of injection holes in the injector as illustrated in FIGS. 2a and 2b are merely illustrative. The shape and number of injector holes may be varied according to the kind and feature of the material to be injected. Also, although FIGS. 2a and 2b illustrate a coaxial injector in which injection holes are arranged on the periphery, this is merely illustrative. A linear injector having linearly arranged injection holes may also be used in other embodiments.

By using the plasma reactor according to the above embodiments, the plasma generated from the plasma generator 10 may be sprayed onto the substrate 1 together with the precursor injected from the injector 20. The plasma reactor may be used for forming a deposition layer on the substrate 1 using the plasma and the precursor or doping a material on the substrate. In addition, the plasma reactor may also be used for plasma treatment of the material on the substrate 1 by spraying plasma from the plasma generator 10 onto the substrate 1 without injecting material from the injector 20.

In case a film is to be formed on the substrate 1 by using the plasma reactor according to an embodiment, the following materials listed in Table 1 may be used as reaction gas (for the plasma generator 10) and the precursor (injected by the injector 20) depending on the type of film to be formed on the substrate 1.

TABLE 1

| | Reaction gas | |
|---|---|---|
| Film formed on | for plasma | |
| substrate | generation | Precursor |
| Si | Ar + H₂ | SiH₄, Si₂H₆, . . . Si₂ₙH₂ₙ₊₂, etc. |
| SiC | Ar + H₂ | Polycarbosilane, |
| | | SiH₄ + CH₄, (CH₃)SiH₃, |
| | | (CH₃)₃SiH, (CH₃)₆Si₂, |
| | | CH₃—SiH₂—CH₂—SiH₃ |
| SiO₂ | Ar + O₂, H₂ | SiH₄ + N₂O, O₂, O₃ |
| | | SiH₂Cl₂ + N₂O, O₂, O₃ |
| SiN | Ar + H₂, NH₃ | SiH₄ + NH₃, N₂ |
| Doped-Si | Ar + H₂ | SiH₄, GeH₄ |
| | | SiH₄ + PH₃, SiH₄ + B₂H₆ |
| | | GeH₄ + PH₃, GeH₄ + B₂H₆ |
| Ti, TiN | Ar + H₂ | TiCl₄, TiCl₄ + NH₃ |
| Si(Ge) | Ar + H₂ | SiH₄, SiH₄ + PH₃, SiH₄ + B₂H₆, GeH₄, |
| | | GeH₄ + PH₃, GeH₄ + B₂H₆ |
| Al₂O₃ | Ar + O₂, H₂ | Dimethylaluminum hydride (DMAH; |
| | | Al(CH₃)₂H), |
| | | Trimethylalane (TMA; Al(CH₃)₃) |
| GaN | Ar + NH₃ | Trimethylgallium (TMGa; Ga(CH₃)₃) |
| ZnO | Ar + O₂, H₂ | Diethyl zinc (DEZ; Zn(CH₃)₂) |

As shown in Table 1, the reaction gas used in the plasma generator 10 may include, among others, argon, nitrogen, hydrogen, ammonia or other suitable materials. Also, the reaction gas may be obtained by mixing argon with hydrogen, oxygen or other suitable materials.

In addition, as shown in Table 1, the precursor injected by the injector 20 may be selected from silicon, silicon compound, germanium compound, aluminum compound, oxygen, ozone, nitrogen, nitrogen compound, titanium compound, carbon compound, gallium compound, zinc compound, other suitable materials, or a combination thereof.

FIG. 1c is a schematic view showing a plasma reactor according to another embodiment. The plasma reactor shown in FIG. 1c is similar to the plasma reactor of FIG. 1a, and thus, the plasma reactor of FIG. 1c is described herein with reference to differences from the plasma reactor of FIG. 1a. Referring to FIG. 1c, the second electrode 12 of the plasma generator 10 further includes a channel 125 for injecting powder or particles. The powder or particles injected into the chamber 13 through the channel 125 helps spraying of plasma. The following materials listed in Table 2 may be used as reaction gas and powder or particles (in the plasma generator 10) and the precursor (injected from the injector 20) depending on the type of film formed on the substrate 1.

TABLE 2

| Film formed on | Reaction gas for | | |
|---|---|---|---|
| substrate | plasma generation | Powder or Particles | Precursor |
| Si | Ar + H₂ | Si, n-doped Si, | SiH₄, Si₂H₆, . . . |
| | | p-doped Si, SiGe | Si₂ₙH₂ₙ₊₂, etc. |
| SiC | Ar + H₂ | Si, Polycarbosilane- | Polycarbosilane, CH₄, |
| | | coated Si, | (CH₃)SiH₃, (CH₃)₆Si₂, |
| | | n-doped Si, | CH₃—SiH₂—CH₂—SiH₃ |
| | | p-doped Si, SiC | |
| SiO₂ | Ar + H₂ | Si, SiO₂ | SiH₄ + N₂O, O₂, O₃ |
| SiN | Ar + H₂ | Si, SiN | SiH₄ + NH₃, N₂ |
| Doped Si | Ar + H₂ | Si, n-doped Si, | SiH₄ + PH₃, |
| | | p-doped Si, SiGe | SiH₄ + B₂H₆, |
| | | | GeH₄ + PH₃, |
| | | | GeH₄ + B₂H₆ |
| | | Filler: Al₂O₃, SiO₂ | SiH₄ + PH₃, |
| | | | SiH₄ + B₂H₆, |
| | | | GeH₄ + PH₃, |
| | | | GeH₄ + B₂H₆ |
| Copper indium | Ar + H₂ | Cu, In, Se | TMGa |
| gallium selenide | | | |
| (CIGS) | | | |
| Si(Ge) | Ar + H₂ | Si, Ge | SiH₄, SiH₄ + PH₃, |
| | | | SiH₄ + B₂H₆, GeH₄, |
| | | | GeH₄ + PH₃, |
| | | | GeH₄ + B₂H₆ |
| TiSi | Ar + H₂ | Si | TiCl₄ |
| ZnO | Ar + H₂ | ZnO | DMAH, TMA, TMGa |
| | | Filler: Al₂O₃, SiO₂ | DEZ, DMAH, TMA, |
| | | | TMGa |

As shown in Table 2, the powder or particles injected into the plasma generator 10 may include, among others, silicon, silicon compound, germanium, germanium compound, copper, indium, selenium, zinc compound or other suitable materials. In addition, the powder or particles may further include filler selected from aluminum compound and silicon compound.

In another embodiment, the following materials listed in Table 3 may be used as reaction gas and powder or particles injected into the plasma generator 10 and the precursor injected from the injector 20 depending on the type of film formed on the substrate 1.

TABLE 3

| | Gas for | | |
|---|---|---|---|
| Film formed on | plasma | | |
| substrate | generation | Powder or Particles | Precursor |
| SiC | Ar + H₂ | Si, SiC, SiN, SiO₂, | Polycarbosilane |
| | | Yttrium-stabilized zirconia | |
| | | (YSZ) | |
| SiC | Ar + H₂ | Polycarbosilane-coated Si, | Polycarbosilane |
| | | SiC, SiN, SiO₂, YSZ | |
| SiC | Ar + CH₄ | Si, SiC, SiN, SiO₂, YSZ | Si, SiC |
| Carbide | Ar + H₂ | Ti, W, Mo | Polycarbosilane |
| Carbide | Ar + H₂ | TiCl₄, WF₆, MoF₆ gas | Polycarbosilane |

As shown in Table 3, the reaction gas injected into the plasma generator 10 may be obtained by mixing argon with hydrogen or hydrocarbon. Also, the powder or particles may be selected from silicon, silicon compound, zirconium compound, titanium, titanium compound, tungsten, tungsten compound, molybdenum, molybdenum compound, other suitable materials, or combinations thereof. The precursor injected by the injector 20 may include polycarbosilane, silicon or silicon compound.

By using the materials listed in Table 3 for the plasma reactor, it is possible to form a deposition film by plasma, spray plasma, or spray plasma and polycarbosilane together. For example, Si plasma or SiC plasma may be sprayed onto the substrate 1 together with polycarbosilane. Also, it is possible to supply Si plasma, SiC plasma or SiH4 plasma to graphite, or to supply polycarbosilane plasma to graphite or silicon. Further, it is possible to spray argon plasma, hydrogen plasma or hydrocarbon plasma to the substrate 1 together with polycarbosilane.

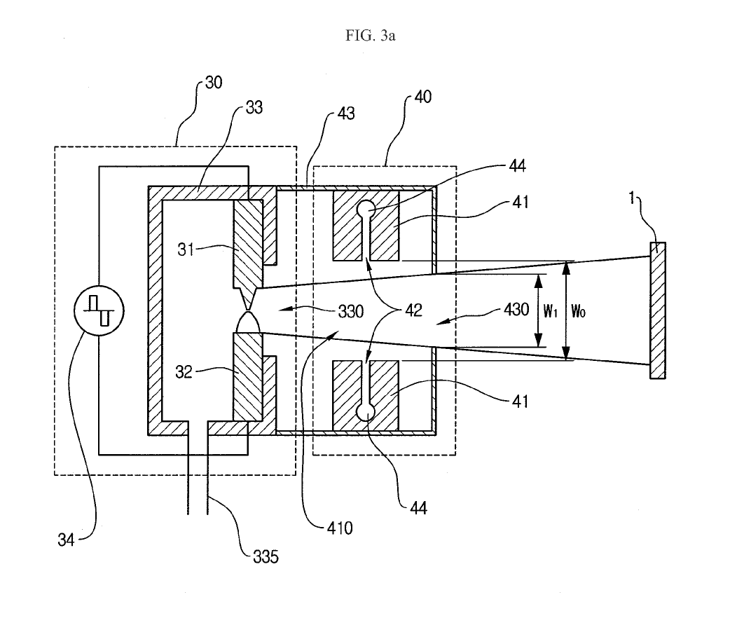

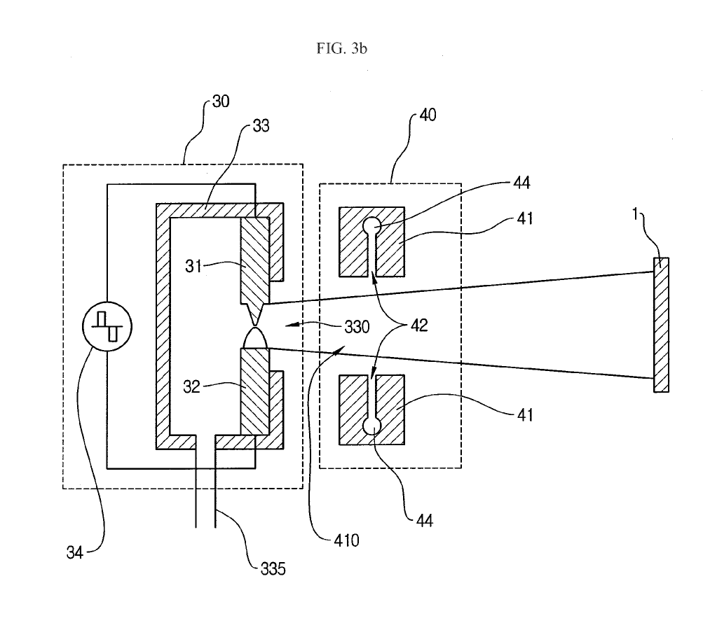

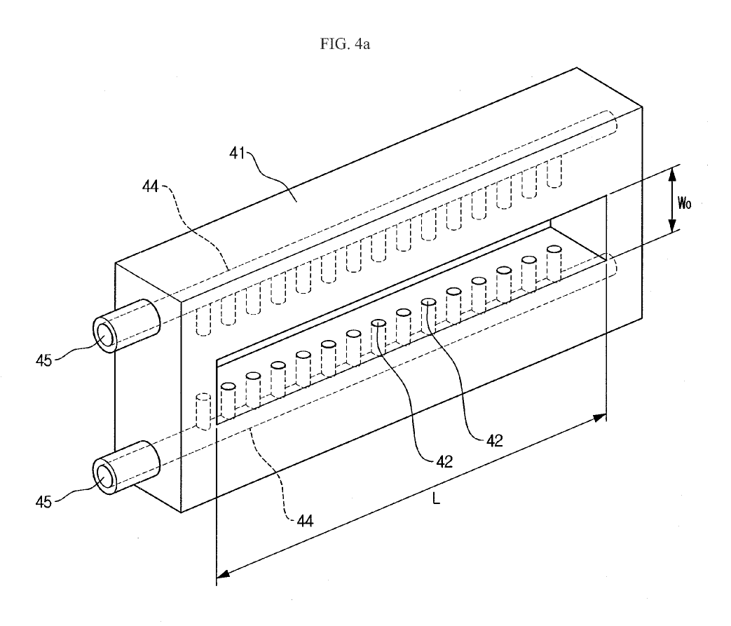

FIG. 3a is a schematic sectional view illustrating a plasma reactor, according to another embodiment. Referring to FIG. 3a, the plasma reactor may include, among others, a plasma generator 30 and an injector 40. The plasma generator 30 and the injector 40 may be located adjacent to each other. The plasma generated from the plasma generator 30 may be sprayed onto the substrate 1 together with a material (for example, a precursor) injected from the injector 40.

The plasma generator 30 may include, among others, a chamber 33, a first electrode 31, a second electrode 32 and a signal generator 34. The first electrode 31 and the second electrode 32 may be located in the chamber 33. The chamber 33 may have an injection port 335. Reaction gas for plasma generation may be injected into the chamber 33 through the injection port 335. Also, the chamber 33 may include a discharge opening 330 through which the plasma is sprayed. The first electrode 31 and the second electrode 32 may face each other. A sharp shaped protrusion (for example, a conical shape) may be formed at one end of the first electrode 31. The first electrode 31 may have a plurality of protrusions arranged in one direction.

The signal generator 34 may be a power supply applying a pulse or square wave patterned signal across the first electrode 31 and the second electrode 32. When power is applied between the first electrode 31 and the second electrode 32, an electric field may be formed in the reaction gas within the chamber 33 that generates corona plasma between the first electrode 31 and the second electrode 32. The generated plasma may be sprayed through the discharge opening 330 of the chamber 33.

In the embodiment illustrated in FIG. 3a, the plasma generator 30 is configured to generate corona plasma. This is merely an example. Different kinds of plasma generators may also be used in other embodiments.

The injector 40 may be located adjacent to the plasma generator 30. The injector 40 may be configured to inject materials such as a precursor. The distance between the injector 40 and the plasma generator 30 may be set differently depending on the structure of the plasma reactor. That is, the injector 40 may be a variable injector.

The injector 40 may include, among others, a platform 41, at least one injection hole 42 formed in the platform 41, and a channel 44. The platform 41 may have an opening 410 of height w0, which opening is aligned with the discharge opening 330 of the chamber 33 through which plasma is sprayed from the plasma generator 30. The height w0 of the opening 410 may be set according to the size of a region to which the plasma and the precursor are to be sprayed.

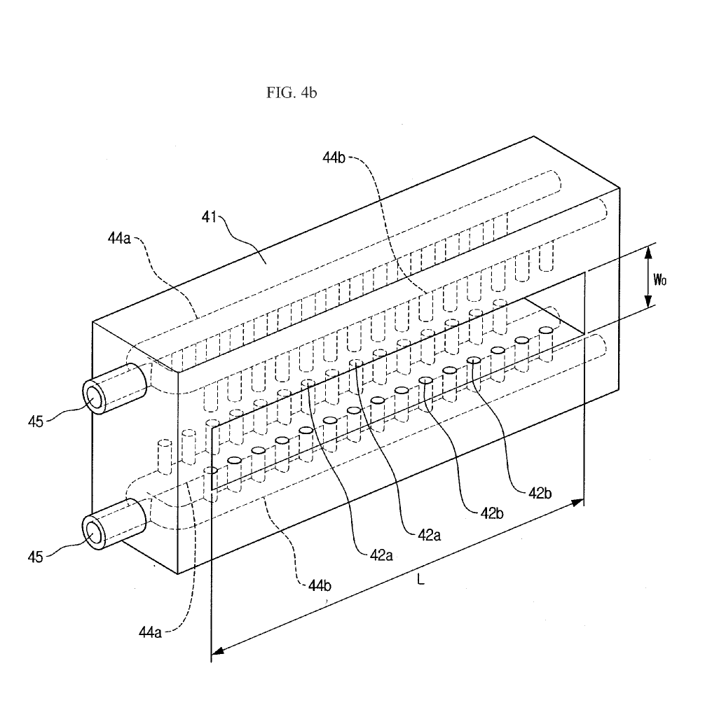

The injection hole 42 is used for injecting the precursor into the opening 410. Thee injection hole 42 may be connected to the channel 44 in the platform 41. The injector 40 may further have an injection port 45 (see FIG. 4a) for injecting the precursor. The precursor injected from an external source is carried through the channel 44, and injected into the opening 410 through the injection hole 42.

In one embodiment, the injector 40 further includes a chamber 43 coupled to the plasma generator 30. In this embodiment, the platform 41 is located in the chamber 43. In case a vacuum condition is required for plasma generation, the platform 41 may be located in the chamber 43 that is maintained in a vacuum state. The chamber 43 may have a discharge hole 430 of height w1 to spray the plasma and the precursor. The discharge hole 430 may be aligned with the opening 410 of the platform 41. The height w1 of the discharge hole 430 may be set according to the size of the region to which the plasma and the precursor are to be sprayed.

Corona plasma may be generated even in a non-vacuous state. Hence, in other embodiments, the platform 41 may be located in open space as shown in FIG. 3b without using the chamber.

FIG. 4a is a schematic perspective view illustrating an injector included in the plasma reactor, according to one embodiment. The injector as illustrated in FIGS. 3a and 3b may correspond to a vertical sectional view of the injector of FIG. 4a. Referring to FIG. 4a, the injector may include, among others, a platform 41. The platform 41 has at least one injection hole 42 and a channel 44 formed therein. The platform 41 may have a polygonal shape and also have an opening 410. The opening 410 may have a rectangular cross-section and have length L and a height w0. However, this is merely an example. The sectional shape and size of the opening 410 may be set according to the shape and size of the region to which plasma is to be sprayed.

At least one injection hole 42 functions to inject a precursor to the opening 410. The injection hole 42 may be disposed along one direction on the surface of the opening 410. For example, the injection holes 42 are arranged in a direction perpendicular to the direction the plasma is sprayed from the plasma generator 10. The injector may include at least one injection port 45 for injecting the precursor to the channel 44. The precursor injected through the injection port 45 may be carried via the channel 44 and then injected into the opening 410 through the injection hole 42. The shape and number of the injection hole 42 and the injection port 45 illustrated in FIG. 4a are merely illustrative. The shape and number may be varied according to the precursors.

FIG. 4b is a schematic perspective view illustrating an injector included in the plasma reactor, according to another embodiment. The injector as shown in FIG. 4b is similar to the injector of FIG. 4a, and thus, the injector of FIG. 4b is described primarily with reference to differences from the injector of FIG. 4a. Referring to FIG. 4b, at least one injection holes 42a, 42b are arranged in a plurality of rows. The injection holes 42a, 42b may be classified into at least one first injection hole 42a arranged in one row and at least one second injection holes 42b arranged in another row. The at least one first injection hole 42a may be connected with each other by a channel 44a. The at least one second injection holes 42b may also be connected with each other by a channel 44b. In one embodiment, both channels 44a, 44b are connected with each other and then to an injection port 45. In another embodiment, both channels 44a, 44b are disconnected from with each other and independently connected to separate injection ports to provide different precursors.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A plasma reactor, comprising:
a plasma generator configured to generate and spray plasma; and
an injector located adjacent to the plasma generator, the injector configured to inject a precursor to the plasma sprayed from the plasma injector.

2. The plasma reactor of claim 1, wherein the injector comprises a platform having a first opening, at least one injection hole and a first channel formed therein, the at least one injection hole provided on the platform to inject the precursor to the opening, and the first channel connected to the at least one first injection hole to carry the precursor to the injection hole.

3. The plasma reactor of claim 2, wherein an injection port is formed in the platform for injecting the precursor into the channel.

4. The plasma reactor of claim 2, further comprising at least one second channel connected to second injection holes.

5. The plasma reactor of claim 4, wherein the first channel carries a first precursor, and the second channel carries a second precursor.

6. The plasma reactor of claim 2, wherein the platform has a polygonal or cylindrical shape.

7. The plasma reactor of claim 2, wherein the injector further comprises a chamber coupled to the plasma generator, the chamber enclosing the platform.

8. The plasma reactor of claim 7, wherein a discharge opening is formed in the chamber for discharging the plasma and the precursor.

9. The plasma reactor of claim 1, wherein the precursor comprises any one selected from a group consisting of silicon, silicon compound, germanium compound, aluminum compound, titanium compound, carbon compound, gallium compound, zinc compound and a combination thereof.

10. The plasma reactor of claim 1, wherein the plasma generator comprises:
a chamber for receiving a reaction gas;
a first electrode and a second electrode facing each other and configured to generate an electric field in the reaction gas in the chamber; and
a power supply connected to the first and second electrodes for applying voltage across the first and second electrodes.

11. The plasma reactor of claim 10, wherein the first electrode has a protrusion.

12. The plasma reactor of claim 10, wherein a hole is formed in the second electrode for discharging the plasma generated from the reaction gas.

13. The plasma reactor of claim 10, wherein the reaction gas comprises argon.

14. The plasma reactor of claim 13, wherein the reaction gas further comprises any one selected from a group consisting of hydrogen, oxygen, hydrocarbon and a combination thereof.

15. The plasma reactor of claim 10, wherein the reaction gas comprises any one selected from a group consisting of nitrogen, hydrogen, ammonia and a combination thereof.

16. The plasma reactor of claim 10, wherein the second electrode comprises a channel for injecting particles into the chamber.

17. The plasma reactor of claim 16, wherein the particles comprise any one selected from a group consisting of silicon, silicon compound, germanium, germanium compound, copper, indium, selenium, zinc compound aluminum compound, zirconium compound, titanium, titanium compound, tungsten, tungsten compound, molybdenum, molybdenum compound and a combination thereof
